(19) United States
(12) Patent Application Publication
(10) Pub. No.: US 2012/0155172 A1
(43) Pub. Date: Jun. 21, 2012

(54) SEMICONDUCTOR MEMORY DEVICE

(76) Inventors: Toshifumi WATANABE, Yokohama-shi (JP); Mitsuhiro Abe, Kawasaki-shi (JP); Kenji Ishizuka, Yokohama-shi (JP)

(21) Appl. No.: 13/242,846

(22) Filed: Sep. 23, 2011

(30) Foreign Application Priority Data
Dec. 17, 2010 (JP) 2010-281384

(51) Int. Cl. G11C 16/06; G11C 7/00

(52) U.S. Cl. 365/185.09; 365/189.2

(57) ABSTRACT

According to one embodiment, a semiconductor memory device includes a first memory and a second memory, a data path between the first memory and the second memory, a register configured to store first data transferred through the data path in a first direction, and a comparison circuit configured to compare second data transferred through the data path in a second direction with the first data stored in the register so as to detect a fault location.

### CROSS-REFERENCE TO RELATED APPLICATIONS

This application is based upon and claims the benefit of priority from prior Japanese Patent Application No. 2010-281384, filed Dec. 17, 2010, the entire contents of which are incorporated herein by reference.

### FIELD

Embodiments described herein relate generally to a semiconductor memory device.

### BACKGROUND

A system LSI that integrates memories of different types on one chip has been developed. Such a semiconductor memory device incorporates a plurality of data paths. To detect the location of a fault in the semiconductor memory device, internal signals are probed, and the results of all test portions are analyzed together. However, when specifying the fault location by this technique, fault analysis is time-consuming.

In addition, when a plurality of memories are formed on one chip, the data paths in the chip are not visually recognizable from the outside. It is therefore difficult to specify the fault location by analyzing the test results. If the fault location cannot be specified, the chip is rejected as a defective product, resulting in a reduction in yield.

### BRIEF DESCRIPTION OF THE DRAWINGS

FIG. 1 is a block diagram showing the arrangement of a memory system 1 according to the first embodiment;

FIG. 2 is a circuit diagram showing the arrangement of a memory cell array 10;

FIG. 3 is a block diagram for implementing the test operation of the memory system 1;

FIG. 4 is a flowchart illustrating test flow (1);

FIG. 5 is a flowchart illustrating test flow (2);

FIG. 6 is a flowchart illustrating test flow (3);

FIG. 7 is a flowchart illustrating test flow (4);

FIG. 8 is a flowchart illustrating test flow (5);

FIG. 9 is a block diagram showing the arrangement of a memory system 1 according to the second embodiment;

FIG. 10 is a circuit diagram showing the arrangement of a comparison circuit 50;

FIG. 11 is a circuit diagram showing the arrangement of an output circuit 54;

FIG. 12 is a flowchart illustrating test flow (6);

FIG. 13 is a block diagram showing the arrangement of a memory system 1 according to the third embodiment;

FIG. 14 is a circuit diagram showing the arrangement of an output circuit 58;

FIG. 15 is a flowchart illustrating test flow (7); and

FIG. 16 is a flowchart illustrating test flow (8).

### DETAILED DESCRIPTION

In general, according to one embodiment, there is provided a semiconductor memory device comprising:

a first memory and a second memory;

a data path between the first memory and the second memory;

a register configured to store first data transferred through the data path in a first direction; and

a comparison circuit configured to compare second data transferred through the data path in a second direction with the first data stored in the register so as to detect a fault location.

The embodiments will be described hereinafter with reference to the accompanying drawings. In the description which follows, the same or functionally equivalent elements are denoted by the same reference numerals, to thereby simplify the description.

### First Embodiment

An example of a semiconductor memory device in which a plurality of kinds of memories are integrated on one chip is OneNAND®. The OneNAND is formed by integrating a NAND flash memory serving as a main memory unit and an SRAM serving as a buffer unit on one chip. In this embodiment, the OneNAND will be exemplified as the semiconductor memory device (memory system) in which a plurality of kinds of memories are integrated on one chip.

### <1. Arrangement of Memory System 1>

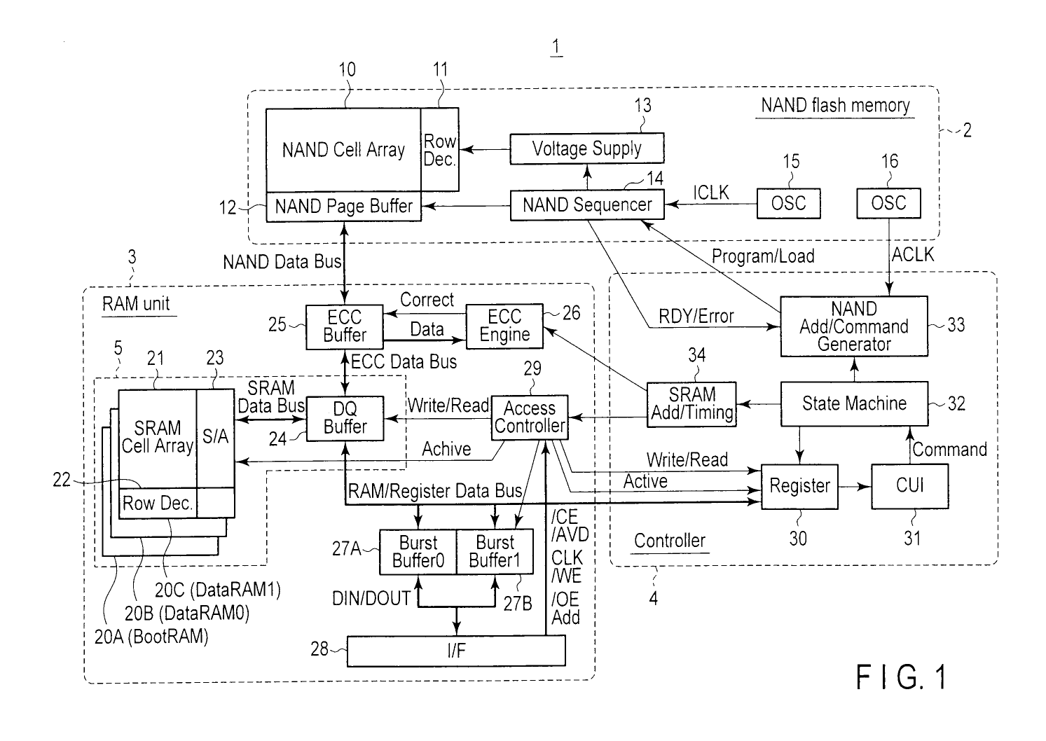

FIG. 1 is a block diagram showing the arrangement of a memory system (OneNAND) 1 according to the first embodiment. The memory system 1 comprises a NAND flash memory 2, a RAM unit 3, and a controller 4. The NAND flash memory 2, the RAM unit 3, and the controller 4 are formed on a single semiconductor substrate and integrated on one chip. The modules included in the memory system 1 will be described below in detail.

### <1-1. NAND Flash Memory 2>

The NAND flash memory 2 functions as the main memory unit of the memory system 1. The NAND flash memory 2 comprises a memory cell array (NAND Cell Array) 10, a row decoder (Row Dec.) 11, a NAND page buffer 12, a voltage generation circuit (Voltage Supply) 13, a NAND sequencer 14, and oscillators (OSC) 15 and 16.

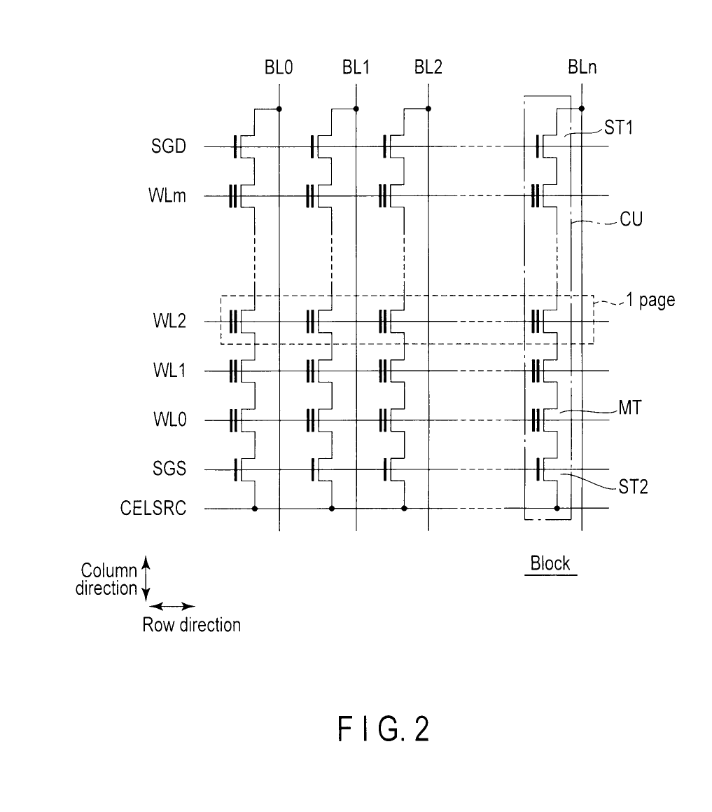

The memory cell array 10 comprises a plurality of memory cell transistors. FIG. 2 is a circuit diagram showing the arrangement of the memory cell array 10. The memory cell array 10 comprises a plurality of memory cell units CU. Each memory cell unit CU includes a plurality of memory cell transistors MT and two select transistors ST1 and ST2. The memory cell transistor MT has a stacked gate structure including a charge storage layer (for example, floating gate electrode) formed on a gate insulating film on the semiconductor substrate, and a control gate electrode formed on a gate insulating film on the charge storage layer. In place of the floating gate structure, the memory cell transistor MT may have a MONOS (Metal Oxide Nitride Oxide Silicon) structure using a method of causing an insulating film (for example, nitride film) serving as a charge storage layer to trap electrons.

The current paths of adjacent memory cell transistors MT in one memory cell unit CU are connected in series. More specifically, (m+1) memory cell transistors MT are connected in series in the column direction so that adjacent transistors share the diffusion region (the source region or drain region). The drain on one end of the series circuit of the memory cell transistors MT is connected to the source of the select transistor ST1. The source on the other end is connected to the drain of the select transistor ST2.

The control gate electrodes of the memory cell transistors MT on the same row are commonly connected to one of a plurality of word lines WL0 to WLm. The gate electrodes of the select transistors ST1 or ST2 on the same row are commonly connected to a select gate line SGD or SGS. The drain of each select transistor ST1 is connected to one of a plurality of bit lines BL0 to BLn. The sources of the select transistors ST2 are commonly connected to a source line CELSRC.

A plurality of memory cell transistors MT connected to the same word line WL constitute a page. Data program and read are executed at once for the memory cell transistors MT in one page. The memory cell array 10 is configured to erase the data of a plurality of pages at once. This erase unit is called a block. FIG. 2 illustrates one extracted block. Actually, the memory cell array 10 comprises a plurality of blocks.

A bit line BL commonly connects the drains of the select transistors ST1 between blocks. That is, the memory cell units CU on the same column in a plurality of blocks are connected to the same bit line BL.

Each memory cell transistor MT can store 1-bit data in accordance with a change in the threshold voltage based on, for example, the amount of electrons injected into the floating gate electrode. The threshold voltage may be controlled more finely to store data of 2 or more bits in each memory cell transistor MT.

Referring to FIG. 1, the row decoder 11 selects the word lines WL0 to WLm and the select gate lines SGD and SGS at the time of data write, read, or erase. The row decoder 11 then applies a necessary voltage to the word lines WL0 to WLm and the select gate lines SGD and SGS.

The NAND page buffer 12 comprises a data latch capable of holding data in the same size as that of one page of the memory cell array 10. More specifically, the NAND page buffer 12 temporarily stores data of one page read from the memory cell array 10 at the time of read, and temporarily stores data of one page to be written to the memory cell array 10 at the time of write. The NAND page buffer 12 also includes a sense amplifier that writes write data to the memory cell array 10 and reads data from the memory cell array 10.

The voltage generation circuit 13 generates a voltage necessary for data write, read, or erase and supplies the voltage to the row decoder 11 and the like.

The NAND sequencer 14 controls the operation of the entire NAND flash memory 2. More specifically, upon receiving various kinds of instructions from the controller 4, the NAND sequencer 14 executes a data write, read, or erase sequence in response to them. In accordance with the sequence, the NAND sequencer 14 controls the operation of the voltage generation circuit 13 or the page buffer 12.

The oscillator 15 generates an internal clock ICLK and supplies it to the NAND sequencer 14. The NAND sequencer 14 operates in synchronism with the internal clock ICLK. The oscillator 16 generates an internal clock ACLK and supplies it to the controller 4 or the RAM unit 3. The internal clock ACLK is a reference clock for the operation of the controller 4 or the RAM unit 3.

### <1-2. RAM Unit 3>

The arrangement of the RAM unit 3 shown in FIG. 1 will be explained next. The RAM unit 3 comprises an SRAM core 5, an ECC (Error Checking and Correcting) buffer 25, an ECC engine 26, burst buffers 27A and 27B, an interface (I/F) 28, and an access controller 29.

In the memory system 1, the NAND flash memory 2 functions as the main memory unit, and the SRAM core 5 of the RAM unit 3 functions as the memory buffer. Hence, to read data from the NAND flash memory 2 to the outside, first, data read from the memory cell array 10 is stored in the SRAM core 5 via the NAND page buffer 12. After that, the data in the SRAM core 5 is transferred to the interface 28 and output to the outside. On the other hand, to store data in the NAND flash memory 2, first, externally input data is stored in the SRAM core 5 via the interface 28. After that, the data in the SRAM core 5 is transferred to the NAND page buffer 12 and written to the memory cell array 10.

In the following description, the operation from data read from the memory cell array 10 until transfer to the SRAM core 5 via the NAND page buffer 12 will be referred to as “load” of data. The operation until the data in the SRAM core 5 is transferred to the interface 28 will be referred to as “read” of data.

The operation until data to be stored in the NAND flash memory 2 is transferred from the interface 28 to the SRAM core 5 will be referred to as “write” of data. The operation until the data in the SRAM core 5 is written to the memory cell array 10 via the NAND page buffer 12 will be referred to as “program” of data.

The SRAM core 5 comprises a plurality of SRAMs 20 (for example, three SRAMs 20A to 20C) and a DQ buffer 24. The DQ buffer 24 temporarily stores data when reading data from the SRAMs 20A to 20C or writing data to the SRAMs 20A to 20C.

Each SRAM 20 comprises a memory cell array (SRAM Cell Array) 21, a row decoder (Row Dec.) 22, and a sense amplifier (S/A) 23. The memory cell array 21 comprises a plurality of memory cells (SRAM cells) arranged in a matrix at the intersections between a plurality of word lines and a plurality of bit line pairs. The row decoder 22 selects a specific word line in the memory cell array 21. The sense amplifier 23 detects and amplifies data from the SRAM cells, and also functions as a load when writing data in the DQ buffer 24 to the SRAM cells.

In this embodiment, for example, the SRAM 20A is a buffer memory that functions as a BootRAM including one bank, that is, bank 0 (1 KB). The SRAM 20B is a buffer memory that functions as DataRAM 0 including two banks, that is, banks 0 and 1 (2 KB). The SRAM 20C is a buffer memory that functions as DataRAM 1 including two banks (2 KB), that is, banks 0 and 1. Note that the number of DataRAMs is not limited to two (DataRAMs 0 and 1), and more DataRAMs may be added.

The ECC buffer 25 is connected to the NAND page buffer 12 via a NAND data bus, and to the DQ buffer 24 via an ECC data bus. The ECC buffer 25 temporarily stores data for ECC processing (error correction in load, and parity generation in program).

The ECC engine 26 detects and corrects errors using data stored in the ECC buffer 25. More specifically, the ECC engine 26 corrects errors in data (Data) input to the ECC buffer 25 and sends the corrected data (Correct) to the ECC buffer 25 again. The ECC buffer 25 and the ECC engine 26 form an ECC circuit.

The burst buffers 27A and 27B are connected to the interface 28 by, for example, a 16-bit wide DIN/DOUT bus, and to the DQ buffer 24 and the controller 4 by a RAM/Register data bus. Each of the burst buffers 27A and 27B temporarily stores data externally input via the interface 28 or data sent from the DQ buffer 24.

The interface 28 supports the same interface standard as that of a NOR flash memory, and exchanges data, control signals, and various signals of addresses and the like with a host device outside the memory system 1. Examples of the control signals are a chip enable signal /CE to enable the entire memory system 1, an address valid signal /AVD to latch an address, a clock CLK for burst read, a write enable signal /WE to enable the write operation, and an output enable signal /OE to enable data output the outside. The interface 28 sends control signals concerning a write request, a read request, or the like from the host device to the access controller 29.

The access controller 29 controls the SRAM core 5 and the controller 4 to execute an operation that satisfies a request from the host device. More specifically, the access controller 29 activates one of the SRAM core 5 and a register 30 (to be described later) of the controller 4 in response to a request from the host device. The access controller 29 then issues a write command or read command (Write/Read) to the SRAM core 5 or the register 30. Upon this control, the SRAM core 5 and the controller 4 start the operation.

### <1-3. Controller 4>

The controller 4 controls the entire memory system 1. The controller 4 comprises the register 30, a command user interface (CUI) 31, a state machine 32, a NAND address/command generation circuit 33, and an SRAM address timing generation circuit (SRAM Add/Timing) 34.

The register 30 is used to set the operation state of a function in accordance with a command from the access controller 29. More specifically, the register 30 holds, for example, a read command or a write command.

When the register 30 holds a predetermined command, the command user interface 31 recognizes that a function execution command is given to the memory system 1. The command user interface 31 then sends an internal command signal (Command) to the state machine 32.

The state machine 32 controls the sequence operation in the memory system 1 based on the internal command signal given by the command user interface 31. The state machine 32 supports a number of functions including write, read, and erase. The state machine 32 controls the operations of the NAND flash memory 2 and the RAM unit 3 so as to execute these functions.

The address/command generation circuit 33 controls the operation of the NAND flash memory 2 based on the control of the state machine 32. More specifically, the address/command generation circuit 33 generates an address, a command (Write/Read/Load), and the like and sends them to the NAND flash memory 2.

The address timing generation circuit 34 controls the operation of the RAM unit 3 based on the control of the state machine 32. More specifically, the address timing generation circuit 34 generates an address and a command necessary for the RAM unit 3 and sends them to the access controller 29 and the ECC engine 26.

In the memory system 1 shown in FIG. 1, the NAND flash memory 2 has long read and write times. On the other hand, the SRAM 20 has shorter read and write times than the NAND flash memory 2. That is, the NAND flash memory 2 and the SRAM 20 have different latencies. Integrating two types of memories with different latencies on one chip makes it possible to increase the processing speed of the memory (NAND flash memory 2) with a long latency when viewed from the outside (host device).

### <2. Test Operation of Memory System 1>

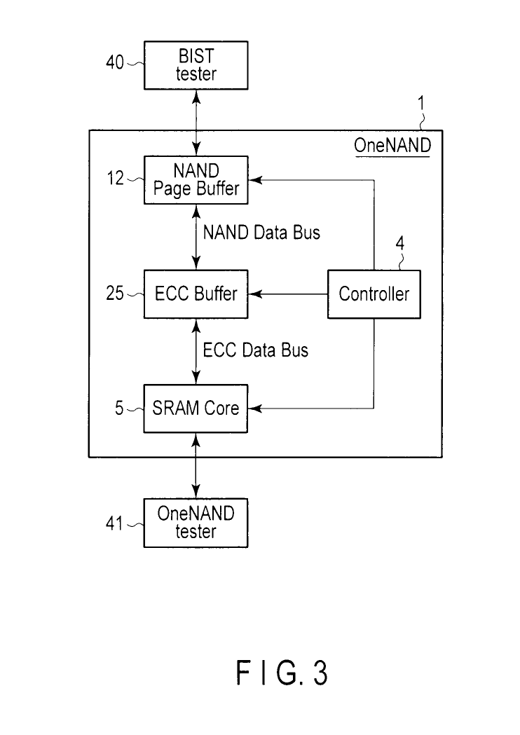

The test operation of the memory system 1 will be described next. FIG. 3 is a block diagram for implementing the test operation of the memory system (OneNAND) 1. FIG. 3 illustrates blocks associated with the test operation, that are extracted from FIG. 1. A BIST (Built-In Self Test) tester 40 is connected to the NAND flash memory 2. The BIST tester 40 directly writes data to the NAND flash memory 2 (more specifically, the NAND page buffer 12) or directly reads data from the NAND page buffer 12. The BIST tester 40 issues commands to the memory system 1.

A OneNAND tester 41 is connected to the memory system 1 via the interface 28. The OneNAND tester 41 tests whether the memory system 1 formed from the OneNAND chip can perform a desired operation. The OneNAND tester 41 writes data to the SRAM core 5 or reads data from the SRAM core 5 via the interface 28. The OneNAND tester 41 issues commands to the memory system 1.

Various kinds of test flows for detecting and specifying a fault location in the memory system 1 will be explained below.

### <2-1. Test Flow (1)>

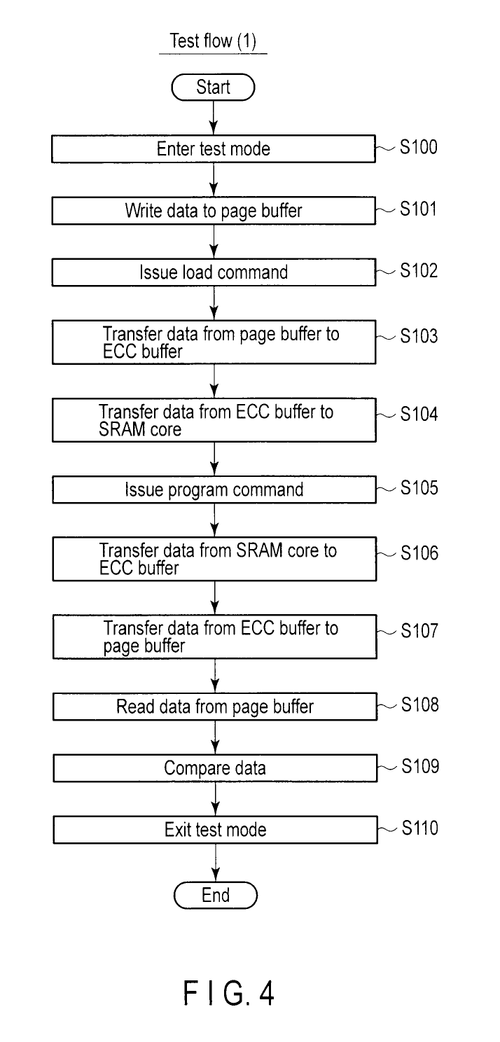

FIG. 4 is a flowchart illustrating test flow (1).

Test flow (1) detects a fault in the data path “NAND page buffer→ECC→SRAM→ECC→NAND page buffer”. In this embodiment, faults include a short, an open, and a ground that occur in the interconnections, elements, and circuits, and a short, an open, and a ground that occur in the interconnections connecting them to each other.

The BIST tester 40 issues, to the memory system 1, a command to enter the test mode (step S100). Upon receiving the command, the state machine 32 recognizes the test mode and enters the test mode. The state machine 32 has various functions for the test mode. The BIST tester 40 directly writes data to the NAND page buffer 12 (step S101). In the normal operation mode other than the test mode, the memory system 1 exchanges data with the host device via the interface 28. In the test mode, the memory system 1 has a function of exchanging data with the outside via the NAND flash memory 2 (mainly the NAND page buffer 12).

The BIST tester 40 issues a load command to the memory system 1 (step S102). Upon receiving the load command, the controller 4 executes the load operation. That is, the NAND page buffer 12 transfers the data to the ECC buffer 25 via the NAND data bus (step S103). The ECC buffer 25 transfers the data to the SRAM core 5 via the ECC data bus (step S104). At this time, error correction by the ECC engine 26 is not performed. The setting to stop the processing of the ECC engine 26 is implemented by causing the BIST tester 40 to set a predetermined flag in the memory system 1.

The BIST tester 40 issues a program command to the memory system 1 (step S105). Upon receiving the program command, the controller 4 executes the program operation. That is, the SRAM core 5 transfers the data to the ECC buffer 25 via the ECC data bus (step S106). The ECC buffer 25 transfers the data to the NAND page buffer 12 via the NAND data bus (step S107). At this time, parity generation by the ECC engine 26 is not performed. The setting to stop the processing of the ECC engine 26 is implemented by causing the OneNAND tester 41 to set a predetermined flag in the memory system 1.

The BIST tester 40 directly reads the data from the NAND page buffer 12 (step S108). The BIST tester 40 compares first data written to the NAND page buffer 12 in step S101 with second data read from the NAND page buffer 12 in step S108 (step S109).

The BIST tester 40 issues, to the memory system 1, a command to exit the test mode. Upon receiving the command, the state machine 32 recognizes the end of the test mode and exits the test mode (step S110).

### <2-2. Test Flow (2)>

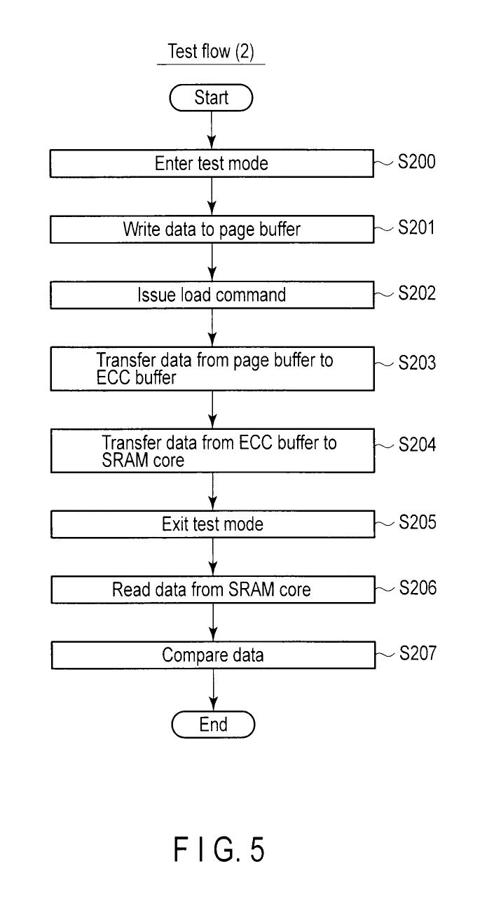

FIG. 5 is a flowchart illustrating test flow (2). Test flow (2) detects a fault in the data path “NAND page buffer→ECC→SRAM”.

Steps S200 to S204 of FIG. 5 are the same as steps S100 to S104 of FIG. 4. The BIST tester 40 issues, to the memory system 1, a command to exit the test mode. Upon receiving the command, the state machine 32 recognizes the end of the test mode and exits the test mode (step S205).

The OneNAND tester 41 issues a read command to the memory system 1 to read data from the SRAM core 5 (step S206). The BIST tester 40 compares the first data written to the NAND page buffer 12 in step S201 with the second data read from the SRAM core 5 in step S206 (step S207).

### <2-3. Test Flow (3)>

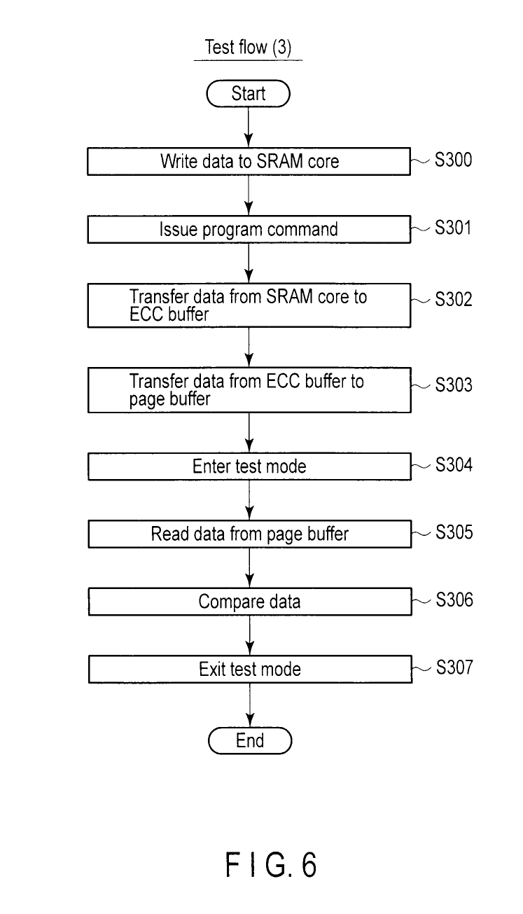

FIG. 6 is a flowchart illustrating test flow (3).

Test flow (3) detects a fault in the data path “SRAM→ECC→NAND page buffer”.

The OneNAND tester 41 issues a write command to the memory system 1 to write data to the SRAM core 5 (step S300). The OneNAND tester 41 then issues a program command to the memory system 1 (step S301). Upon receiving the program command, the controller 4 executes the program operation. That is, the SRAM core 5 transfers the data to the ECC buffer 25 via the ECC data bus (step S302). The ECC buffer 25 transfers the data to the NAND page buffer 12 via the NAND data bus (step S303).

The BIST tester 40 issues, to the memory system 1, a command to enter the test mode (step S304). Upon receiving the command, the state machine 32 recognizes the test mode and enters the test mode. The BIST tester 40 directly reads the data from the NAND page buffer 12 (step S305). The BIST tester 40 compares the first data written to the SRAM core 5 in step S300 with the second data read from the NAND page buffer 12 in step S305 (step S306).

The BIST tester 40 issues, to the memory system 1, a command to exit the test mode. Upon receiving the command, the state machine 32 recognizes the end of the test mode and exits the test mode (step S307).

### <2-4. Test Flow (4)>

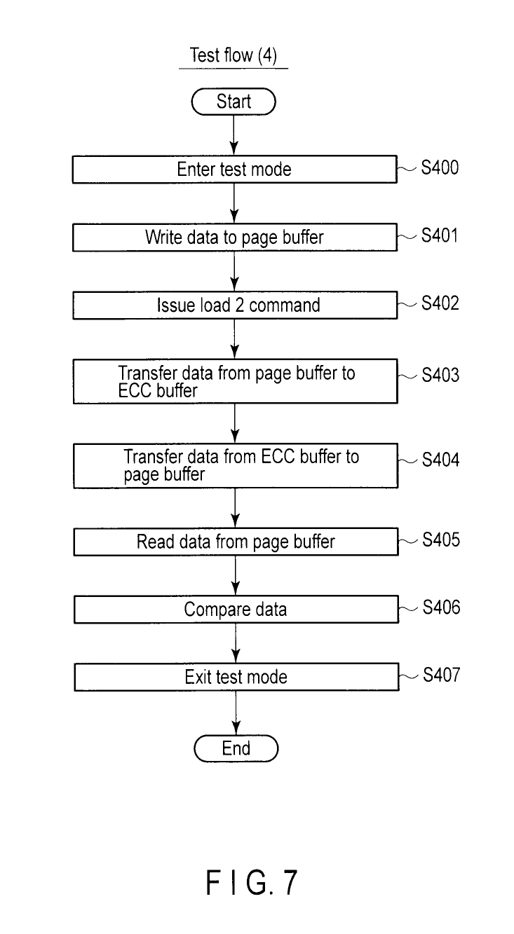

FIG. 7 is a flowchart illustrating test flow (4). Test flow (4) detects a fault in the data path “NAND page buffer→ECC→NAND page buffer”.

Steps S400 to S401 of FIG. 7 are the same as steps S100 to S101 of FIG. 4. The BIST tester 40 issues a load 2 command to the memory system 1 (step S402). The load 2 command is used to transfer data via a data path passing through the NAND page buffer 12, the ECC buffer 25, and the NAND page buffer 12.

Upon receiving the load 2 command, the controller 4 executes the load operation corresponding to the load 2 command. That is, the NAND page buffer 12 transfers the data to the ECC buffer 25 via the NAND data bus (step S403). The ECC buffer 25 transfers the data to the NAND page buffer 12 via the NAND data bus (step S404).

The BIST tester 40 directly reads the data from the NAND page buffer 12 (step S405). The BIST tester 40 compares the first data written to the NAND page buffer 12 in step S401 with the second data read from the NAND page buffer 12 in step S405 (step S406).

The BIST tester 40 issues, to the memory system 1, a command to exit the test mode. Upon receiving the command, the state machine 32 recognizes the end of the test mode and exits the test mode (step S407).

### <2-5. Test Flow (5)>

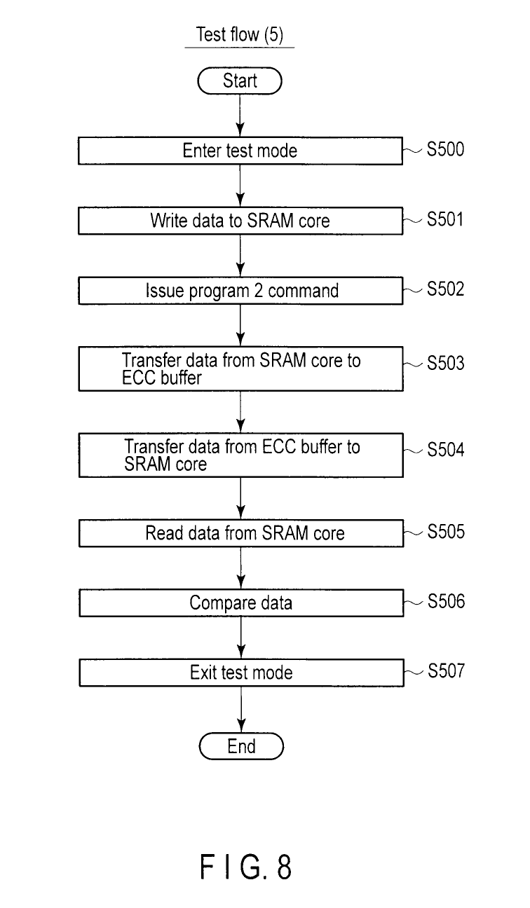

FIG. 8 is a flowchart illustrating test flow (5). Test flow (5) detects a fault in the data path “SRAM→ECC→SRAM”.

The OneNAND tester 41 issues, to the memory system 1, a command to enter the test mode (step S500). Upon receiving the command, the state machine 32 recognizes the test mode and enters the test mode.

The OneNAND tester 41 issues a write command to the memory system 1 to write data to the SRAM core 5 (step S501). The OneNAND tester 41 then issues a program 2 command to the memory system 1 (step S502). The program 2 command is used to transfer data via a data path passing through the SRAM core 5, the ECC buffer 25, and the SRAM core 5.

Upon receiving the program 2 command, the controller 4 executes the program operation corresponding to the program 2 command. That is, the SRAM core 5 transfers the data to the ECC buffer 25 via the ECC data bus (step S503). The ECC buffer 25 transfers the data to the SRAM core 5 via the ECC data bus (step S504).

The OneNAND tester 41 issues a read command to the memory system 1 to read the data from the SRAM core 5 (step S505). The OneNAND tester 41 compares the first data written to the SRAM core 5 in step S501 with the second data read from the SRAM core 5 in step S505 (step S506).

The OneNAND tester 41 issues, to the memory system 1, a command to exit the test mode. Upon receiving the command, the state machine 32 recognizes the end of the test mode and exits the test mode (step S507).

### <2-6. Fault Location Determination Method>

The use of test flows (1) to (5) enables fault detection in all data paths of the memory system 1. It is therefore possible to specify a fault location by combining the detection results of test flows (1) to (5).

Test flow (1) is executed through all data paths. For this reason, if test flow (1) is passed, the absence of faults in the memory system 1 can be confirmed. On the other hand, if test flow (1) fails, a fault has occurred in at least one data path of the memory system 1. To specify the fault location, another test flow is additionally executed.

Examples of fault location determination will be described below.

### EXAMPLE 1

When test flow (1)=fail, test flow (2)=fail, and test flow (4)=fail, the fault location is specified to be in the data path “NAND page buffer 12→ECC buffer 25”.

### EXAMPLE 2

When test flow (1)=fail, test flow (2)=fail, and test flow (5)=fail, the fault location is specified to be in the data path “ECC buffer 25→SRAM core 5”.

### EXAMPLE 3

When test flow (1)=fail, test flow (3)=fail, and test flow (4)=fail, the fault location is specified to be in the data path “ECC buffer 25→NAND page buffer 12”.

### EXAMPLE 4

When test flow (1)=fail, test flow (3)=fail, and test flow (5)=fail, the fault location is specified to be in the data path “SRAM core 5→ECC buffer 25”.

### <3. Effects>

As described above in detail, according to the first embodiment, in the memory system 1 in which the NAND flash memory 2 and the SRAM 20 having different latencies and the ECC circuit (the ECC buffer 25 and the ECC engine 26) are integrated on one chip, the BIST tester 40 is connected to the NAND flash memory 2, and the OneNAND tester 41 is connected to the SRAM 20 via the interface 28. A plurality of test flows for detecting a fault location are executed for a plurality of data paths of the memory system 1 using the BIST tester 40 and the OneNAND tester 41.

Hence, according to the first embodiment, a location where a fault has occurred or a shortest data path where a fault has occurred can easily be specified by comparing the detection results of the plurality of test flows. This allows to reduce the test cost as compared to the test method of probing internal signals.

In addition, since a measure can be taken to repair a fault location or disable a data path including a fault location, defective products can be reduced. This enables to reduce the manufacturing cost.

Especially for a chip that has an internal data path visually unrecognizable from the outside and exchanges data with the outside (host device) only via an interface, executing the test method of this embodiment allows to inexpensively specify the fault location.

### Second Embodiment

In the first embodiment, data read by the tester are compared outside the chip, and the fault location is determined based on the comparison result. In the second embodiment, a comparison circuit configured to compare data is provided inside a memory system 1, and the comparison circuit compares data necessary for fault detection.

### <1. Arrangement of Memory System 1>

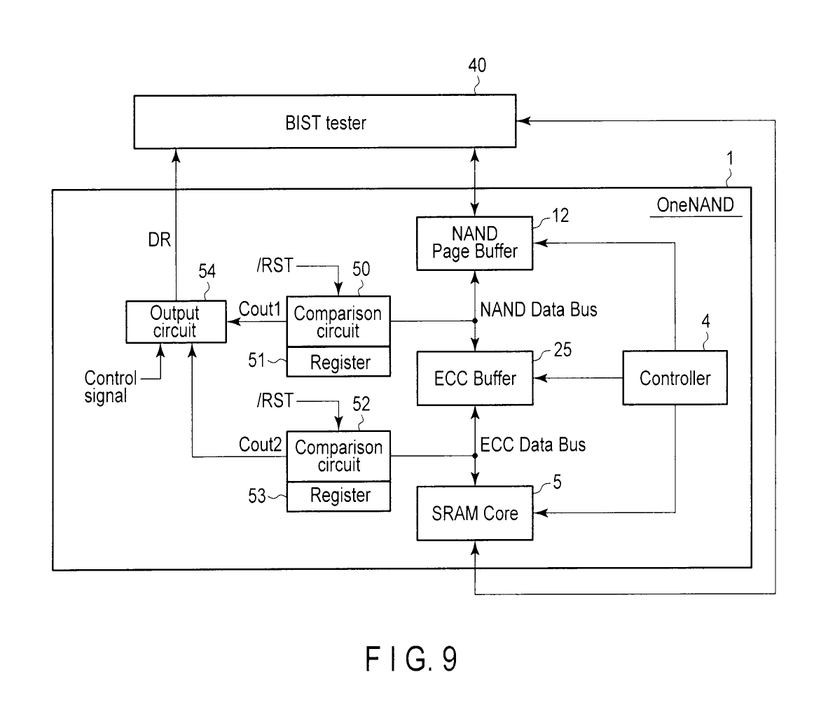

FIG. 9 is a block diagram showing the arrangement of the memory system (OneNAND) 1 according to the second embodiment. The memory system 1 comprises comparison circuits 50 and 52, registers 51 and 53, and an output circuit 54 in addition to the blocks shown in FIG. 1. FIG. 9 illustrates a controller 4, an SRAM core 5, a NAND page buffer 12, and an ECC buffer 25 extracted out of the blocks of FIG. 1. The components other than these blocks are the same as in FIG. 1.

A BIST tester 40 is connected to a NAND flash memory 2 and also to the SRAM core 5 via an interface 28.

The comparison circuit 50 is connected to the NAND data bus. The comparison circuit 50 compares output data output from the NAND page buffer 12 with input data input to the NAND page buffer 12. The comparison circuit 50 outputs a flag Cout1 that is the comparison result of the output data and the input data. The comparison circuit 50 is reset by a reset signal /RST sent from the BIST tester 40. The register 51 stores the output data output from the NAND page buffer 12, that is, the data transferred from the NAND page buffer 12 to the ECC buffer 25.

The comparison circuit 52 is connected to the ECC data bus. The comparison circuit 52 compares output data output from the SRAM core 5 with input data input to the SRAM core 5. The comparison circuit 52 outputs a flag Cout2 that is the comparison result of the output data and the input data. The comparison circuit 52 is reset by the reset signal /RST sent from the BIST tester 40. The register 53 stores the output data output from the SRAM core 5, that is, the data transferred from the SRAM core 5 to the ECC buffer 25.

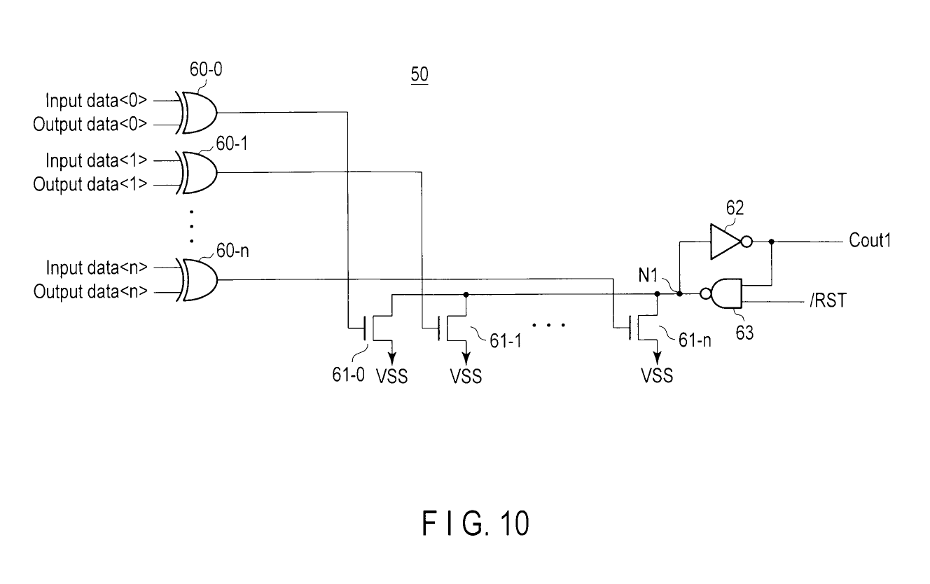

FIG. 10 is a circuit diagram showing the arrangement of the comparison circuit 50. The comparison circuit 50 comprises exclusive OR circuits (XOR circuits) 60-0 to 60-n as many as the bits of the data bus, N-channel MOSFETs 61-0 to 61-n as many as the XOR circuits 60-0 to 60-n , an inverter circuit 62, and a NAND circuit 63.

Input data <n>and output data <n> are input to the two input terminals of the nth XOR circuit 60-n , respectively. The output terminal of the XOR circuit 60-n is connected to the gate of the NMOSFET 61-n . The NMOSFET 61-n has its source connected to a ground terminal VSS, and its drain connected to a node N1.

The input terminal of the inverter circuit 62 is connected to the node N1. The inverter circuit 62 outputs the flag Cout1 of low level when the outputs of all the XOR circuits 60-0 to 60-n are at low level, and outputs the flag Cout1 of high level otherwise. The first input terminal of the NAND circuit 63 is connected to the output terminal of the inverter circuit 62. The reset signal /RST is supplied to the second input terminal of the NAND circuit 63. When the reset signal /RST is at low level, the NAND circuit 63 resets the node N1 to high level. The arrangement of the comparison circuit 52 is the same as that of the comparison circuit 50.

The output circuit 54 shown in FIG. 9 receives the flag Cout1 from the comparison circuit 50 and the flag Cout2 from the comparison circuit 52. The output circuit 54 outputs a detection result DR to the BIST tester 40 based on the flags Cout1 and Cout2.

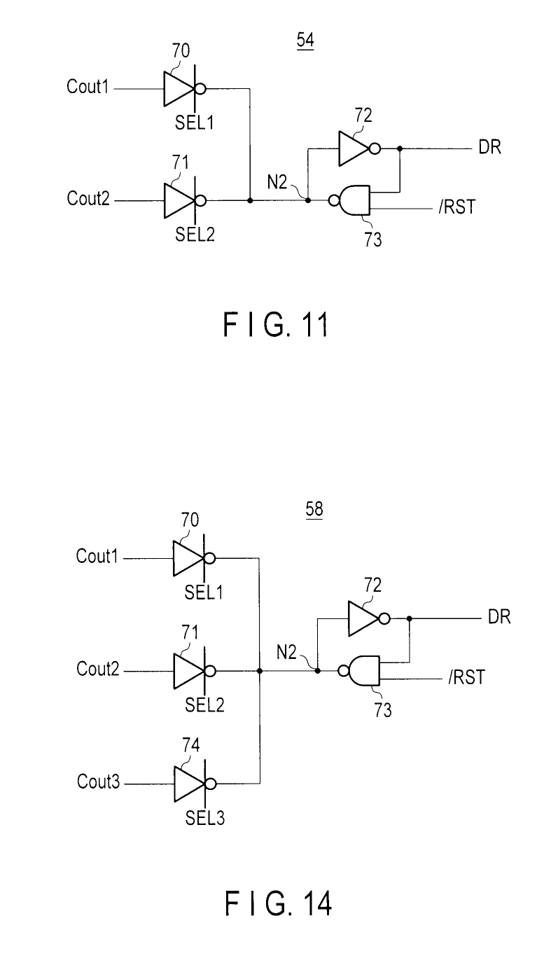

FIG. 11 is a circuit diagram showing the arrangement of the output circuit 54. The output circuit 54 comprises clocked inverter circuits 70 and 71 in number corresponding to the comparison circuits 50 and 52, an inverter circuit 72, and a NAND circuit 73.

The flag Cout1 is input to the input terminal of the clocked inverter circuit 70. The output of the clocked inverter circuit 70 is connected to a node N2. The clocked inverter circuit 70 operates when a control signal SEL1 sent from the BIST tester 40 is at high level. The flag Cout2 is input to the input terminal of the clocked inverter circuit 71. The output of the clocked inverter circuit 71 is connected to the node N2. The clocked inverter circuit 71 operates when a control signal SEL2 sent from the BIST tester 40 is at high level.

The input terminal of the inverter circuit 72 is connected to the node N2. The inverter circuit 72 inverts data sent from the clocked inverter circuit 70 or 71 to the node N2 and outputs it. The first input terminal of the NAND circuit 73 is connected to the output terminal of the inverter circuit 72. The reset signal /RST is supplied to the second input terminal of the NAND circuit 73. When the reset signal /RST is at low level, the NAND circuit 73 resets the node N2 to high level.

### <2. Test Operation of Memory System 1>

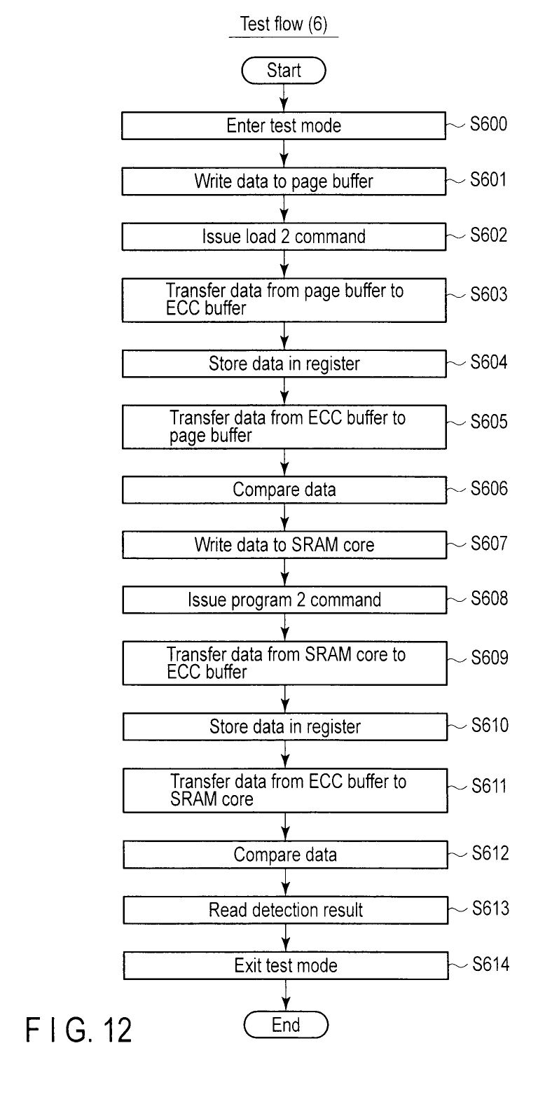

The test operation of the memory system 1 will be described next. FIG. 12 is a flowchart illustrating test flow (6).

The BIST tester 40 issues, to the memory system 1, a command to enter the test mode (step S600). Upon receiving the command, a state machine 32 recognizes the test mode and enters the test mode. The BIST tester 40 directly writes data to the NAND page buffer 12 (step S601).

The BIST tester 40 issues a load 2 command to the memory system 1 (step S602). Upon receiving the load 2 command, the controller 4 executes the load operation corresponding to the load 2 command. That is, the NAND page buffer 12 transfers the data to the ECC buffer 25 via the NAND data bus (step S603). The register 51 stores the data transferred in step 5603 (step S604). The ECC buffer 25 transfers the data to the NAND page buffer 12 via the NAND data bus (step S605).

The comparison circuit 50 compares the data transferred in step S605 with the data stored in the register 51, and determines whether the two data match (step S606). The comparison circuit 50 sends, to the output circuit 54, the flag Cout1 that changes to low level when the two data match or to high level when the two data are different.

The BIST tester 40 issues a write command to the memory system 1 to write data to the SRAM core 5 (step S607). The BIST tester 40 then issues a program 2 command to the memory system 1 (step S608). Upon receiving the program 2 command, the controller 4 executes the program operation corresponding to the program 2 command. That is, the SRAM core 5 transfers the data to the ECC buffer 25 via the ECC data bus (step S609). The register 53 stores the data transferred in step S609 (step S610). The ECC buffer 25 transfers the data to the SRAM core 5 via the ECC data bus (step S611).

The comparison circuit 52 compares the data transferred in step S611 with the data stored in the register 53, and determines whether the two data match (step S612). The comparison circuit 52 sends, to the output circuit 54, the flag Cout2 that changes to low level when the two data match or to high level when the two data are different.

The BIST tester 40 supplies the control signals SEL1 and SEL2 to the output circuit 54 to read the detection result DR (step S613). The fault location can be specified based on the detection result DR. Note that as the detection result DR, the flags Cout1 and Cout2 can sequentially be read in synchronism with clocks, or the OR of all flags can be output.

The BIST tester 40 issues, to the memory system 1, a command to exit the test mode. Upon receiving the command, the state machine 32 recognizes the end of the test mode and exits the test mode (step S614).

### <3. Effects>

As described above in detail, according to the second embodiment, a location where a fault has occurred or a shortest data path where a fault has occurred can easily be specified. This allows to reduce the test cost.

In addition, data necessary for fault detection can be compared inside the memory system 1. Since no expensive test device need be used, the test cost can be reduced. The test time can also be shortened.

### Third Embodiment

In the third embodiment, a memory system 1 includes a plurality of latch circuits for pipeline processing. Data comparison is done between the input and output terminals of each latch circuit, thereby detecting a fault in each latch circuit.

### <1. Arrangement of Memory System 1>

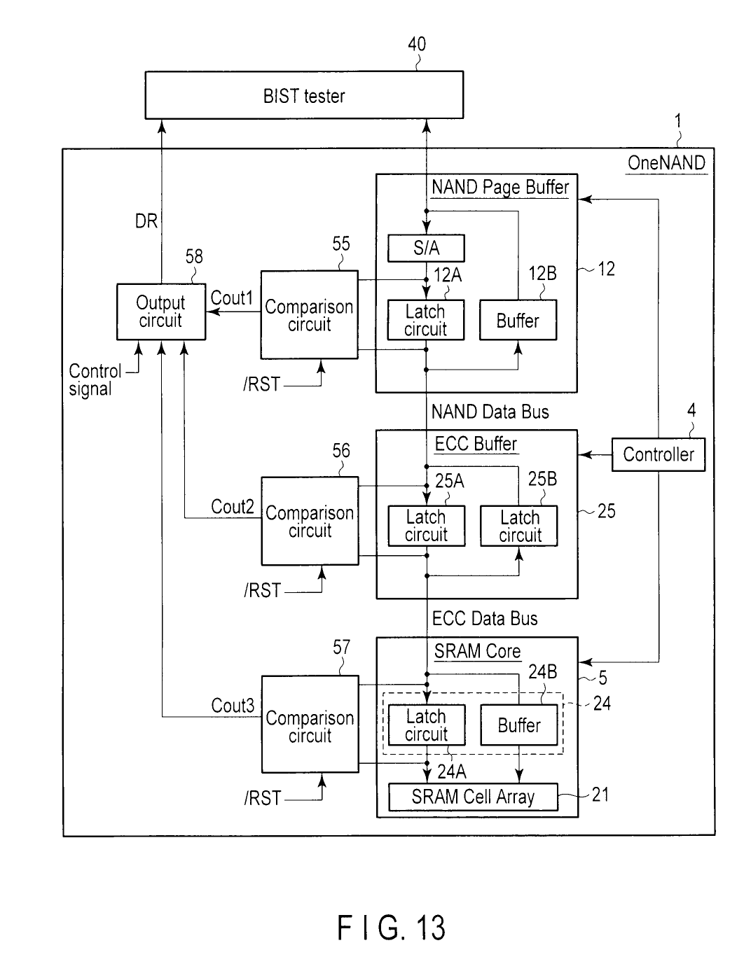

FIG. 13 is a block diagram showing the arrangement of the memory system (OneNAND) 1 according to the third embodiment. The memory system 1 comprises comparison circuits 55 to 57 and an output circuit 58 in addition to the blocks shown in FIG. 1. FIG. 13 illustrates a controller 4, an SRAM core 5, a NAND page buffer 12, and an ECC buffer 25 extracted out of the blocks of FIG. 1. The components other than these blocks are the same as in FIG. 1. A BIST tester 40 is connected to a NAND flash memory 2.

The NAND page buffer 12 comprises a sense amplifier S/A, a latch circuit 12A and a buffer 12B. One terminal of the sense amplifier S/A is connected to a memory cell array 10. The other terminal of the sense amplifier S/A is connected to one terminal of the latch circuit 12A. The other terminal of the latch circuit 12A is connected to the NAND data bus. One terminal of the buffer 12B is connected to the NAND data bus. The other terminal of the buffer 12B is connected to the one terminal of the sense amplifier S/A.

The ECC buffer 25 comprises latch circuits 25A and 25B. One terminal of each of the latch circuits 25A and 25B is connected to the NAND data bus. The other terminal of each of the latch circuits 25A and 25B is connected to the ECC data bus.

A DQ buffer 24 included in the SRAM core 5 comprises a latch circuit 24A and a buffer 24B. One terminal of each of the latch circuit 24A and the buffer 24B is connected to the ECC data bus. The other terminal of each of the latch circuit 24A and the buffer 24B is connected to a memory cell array 21 via a sense amplifier 23 (not shown).

In the load operation, the data path passes through “latch circuit 12A→latch circuit 25A→latch circuit 24A”. In the program operation, the data path passes through “buffer 24B→latch circuit 25B→buffer 12B”.

The comparison circuit 55 is connected across the latch circuit 12A. The comparison circuit 55 compares input data input to the latch circuit 12A with output data output from the latch circuit 12A. The comparison circuit 55 outputs a flag Cout1 that is the comparison result of the input data and the output data.

The comparison circuit 56 is connected across both the latch circuits 25A and 25B. The comparison circuit 56 compares input data input to the latch circuit 25A with output data output from the latch circuit 25A. The comparison circuit 56 also compares input data input to the latch circuit 25B with output data output from the latch circuit 25B. The comparison circuit 56 outputs a flag Cout2 that is the comparison result of the input data and the output data.

The comparison circuit 57 is connected across the latch circuit 24A. The comparison circuit 57 compares input data input to the latch circuit 24A with output data output from the latch circuit 24A. The comparison circuit 57 outputs a flag Cout3 that is the comparison result of the input data and the output data. The comparison circuits 55 to 57 are reset by a reset signal /RST sent from the BIST tester 40. Note that the arrangement of the comparison circuits 55 to 57 is the same as in FIG. 10.

The output circuit 58 receives the flag Cout1 from the comparison circuit 55, the flag Cout2 from the comparison circuit 56, and the flag Cout3 from the comparison circuit 57. The output circuit 58 outputs a detection result DR to the BIST tester 40 based on the flags Cout1 to Cout3.

FIG. 14 is a circuit diagram showing the arrangement of the output circuit 58. The output circuit 58 comprises a clocked inverter circuit 74 for the flag Cout3 in addition to the circuits shown in FIG. 11. The clocked inverter circuit 74 operates when a control signal SEL3 sent from the BIST tester 40 is at high level.

### <2. Test Operation of Memory System 1>

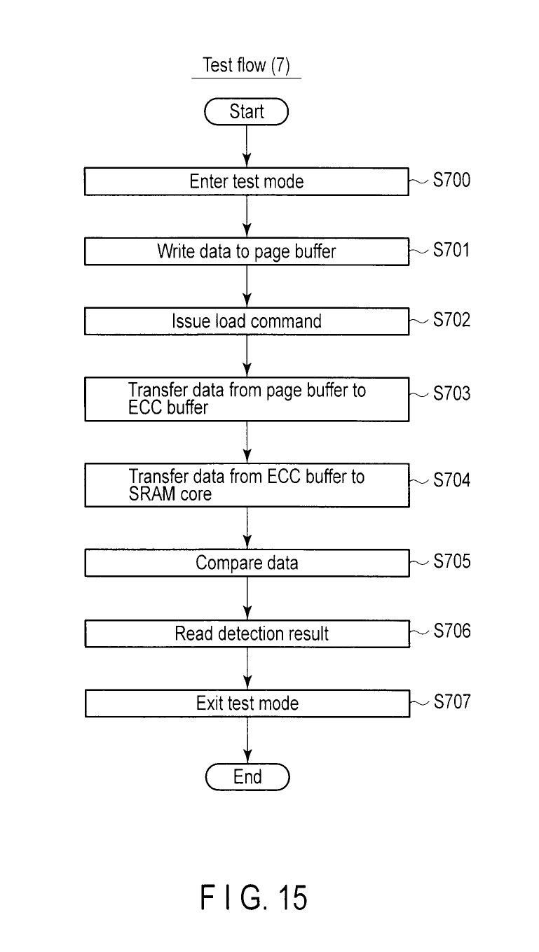

FIG. 15 is a flowchart illustrating test flow (7). Test flow (7) detects a fault in the data path “page buffer→ECC→SRAM”, that is, the data path in the load operation.

Steps S700 and S701 of FIG. 15 are the same as steps S100 and S101 of FIG. 4. The BIST tester 40 issues a load command to the memory system 1 (step S702). Upon receiving the load command, the controller 4 executes the load operation. That is, the NAND page buffer 12 transfers the data to the ECC buffer 25 via the NAND data bus (step S703). The ECC buffer 25 transfers the data to the SRAM core 5 via the ECC data bus (step S704).

Parallel to the load operation, the comparison circuits 55 to 57 perform data comparison (step S705). The comparison circuits 55 to 57 send the flags Cout1 to Cout3 to the output circuit 58, respectively. More specifically, each comparison circuit sends, to the output circuit 58, the flag Cout that changes to low level when the two data match or to high level when the two data are different.

The BIST tester 40 supplies the control signals SEL1 to SEL3 to the output circuit 58 to read the detection result DR (step S706). The latch circuit that has failed can be detected based on the detection result DR. Note that as the detection result DR, the flags Cout1 to Cout3 can sequentially be read in synchronism with clocks, or the OR of all flags can be output.

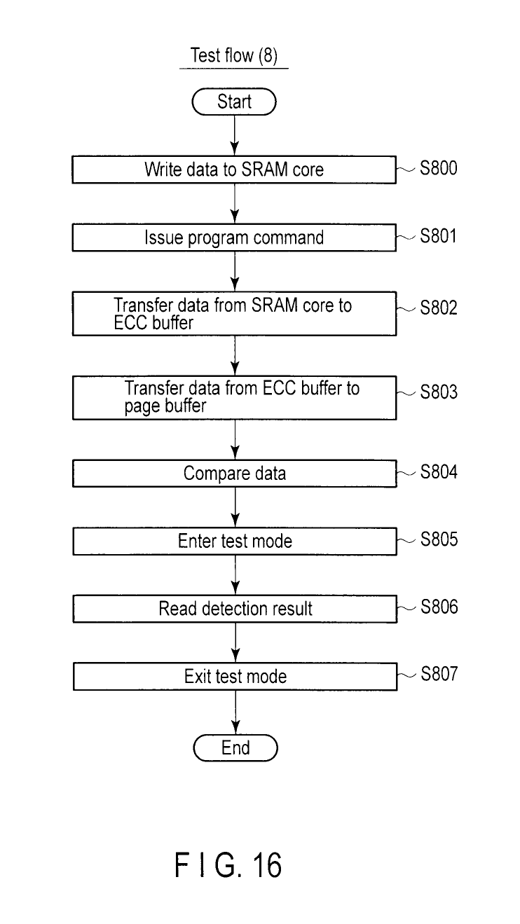

The BIST tester 40 issues, to the memory system 1, a command to exit the test mode. Upon receiving the command, a state machine 32 recognizes the end of the test mode and exits the test mode (step S707). FIG. 16 is a flowchart illustrating test flow (8).

Test flow (8) detects a fault in the data path “SRAM→ECC→page buffer”, that is, the data path in the program operation.

Steps S800 to S803 of FIG. 16 are the same as steps S300 to S303 of FIG. 6. Parallel to the program operation, the comparison circuit 56 performs data comparison (step S804). The comparison circuit 56 sends the flag Cout2 to the output circuit 58. More specifically, the comparison circuit 56 sends, to the output circuit 58, the flag Cout2 that changes to low level when the two data match or to high level when the two data are different.

The BIST tester 40 issues, to the memory system 1, a command to enter the test mode (step S805). Upon receiving the command, the state machine 32 recognizes the test mode and enters the test mode.

The BIST tester 40 supplies the control signal SEL2 to the output circuit 58 to read the detection result DR (step S806). A faulty latch circuit can be detected based on the detection result DR.

The BIST tester 40 issues, to the memory system 1, a command to exit the test mode. Upon receiving the command, the state machine 32 recognizes the end of the test mode and exits the test mode (step S807).

### <3. Effects>

As described above in detail, according to the third embodiment, a faulty latch circuit can be detected from the plurality of latch circuits included in the NAND flash memory 2, the SRAM core 5, and the ECC buffer 25. In addition, data necessary for fault detection can be compared inside the memory system 1. Since no expensive test device need be used, the test cost can be reduced. The test time can also shorten.

Furthermore, since a measure can be taken to repair a faulty latch circuit or disable a data path including a fault location, defective products can be reduced. This enables to reduce the manufacturing cost.

Note that in this embodiment, the memory system in which the NAND flash memory and the SRAMs are integrated on one chip is used. However, the types of memory to be integrated on one chip are not limited to the NAND flash memory and the SRAM. The embodiment is also applicable to a chip including, for example, a plurality of memories with different latencies.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first memory and a second memory;
a data path between the first memory and the second memory;
a register configured to store first data transferred through the data path in a first direction; and
a comparison circuit configured to compare second data transferred through the data path in a second direction with the first data stored in the register so as to detect a fault location.

2. The device of claim 1, further comprising a control circuit configured to sequentially transfer data to the first memory, the second memory, and the first memory in a test mode.

3. The device of claim 1, further comprising an output circuit configured to output a comparison result of the comparison circuit to an outside in accordance with a control signal.

4. The device of claim 1, wherein
the first memory receives the first data from a tester and transfers the first data to the second memory, and
the second memory receives the second data from the tester and transfers the second data to the first memory.

5. The device of claim 1, wherein
the comparison circuit includes an XOR gate and an n-type MOSFET,
the XOR gate has a first input terminal for receiving the first data and a second terminal for receiving the second data, and
the MOSFET has a gate connected to a output terminal of the XOR gate, a grounded source, and a drain for outputting a comparison result.

6. The device of claim 3, wherein the output circuit includes a clocked inverter circuit having a input terminal for receiving the comparison result and a control terminal for receiving the control signal.

7. The device of claim 1, wherein the first memory and the second memory are mounted on one chip.

8. The device of claim 1, wherein
the first memory comprises a NAND flash memory, and
the second memory comprises an SRAM.

9. A semiconductor memory device comprising:
a memory;
an ECC circuit configured to correct an error of data stored in the memory;
a data path between the memory and the ECC circuit;
a register configured to store first data transferred through the data path in a first direction; and
a comparison circuit configured to compare second data transferred through the data path in a second direction with the first data stored in the register so as to detect a fault location.

10. The device of claim 9, further comprising a control circuit configured to sequentially transfer data to the memory, the ECC circuit, and the memory in a test mode.

11. The device of claim 9, further comprising an output circuit configured to output a comparison result of the comparison circuit to an outside in accordance with a control signal.

12. The device of claim 9, wherein
the memory receives the first data from a tester and transfers the first data to the ECC circuit, and
the ECC circuit receives the second data from the tester and transfers the second data to the memory.

13. The device of claim 9, wherein the memory and the ECC circuit are mounted on one chip.

14. The device of claim 9, wherein the memory comprises a NAND flash memory.

15. A semiconductor memory device comprising:
a first memory and a second memory;
a data path between the first memory and the second memory;
a latch circuit provided in the data path; and
a comparison circuit configured to compare first data input to the latch circuit with second data output from the latch circuit so as to detect a fault location.

16. The device of claim 15, further comprising a control circuit configured to transfer data from the first memory to the second memory in a test mode.

17. The device of claim 15, further comprising an output circuit configured to output a comparison result of the comparison circuit to an outside in accordance with a control signal.

18. The device of claim 15, wherein the first memory receives the first data from a tester and transfers the first data to the second memory.

19. The device of claim 17, wherein the output circuit includes a clocked inverter circuit having a input terminal for receiving the comparison result and a control terminal for receiving the control signal.

20. The device of claim 15, wherein
the first memory comprises a NAND flash memory, and
the second memory comprises an SRAM.
